(19) United States
(12) Patent Application Publication
(10) Pub. No.: US 2007/0220737 A1
(43) Pub. Date: Sep. 27, 2007

(54) INTEGRATED CIRCUIT TEST RESULT COMMUNICATION

(76) Inventors: Anthony Stoughton, Seattle, WA (US); Michael Manley, Seattle, WA (US); Christopher Segura, Seattle, WA (US); Ronald Lee Koepp, Seattle, WA (US); Ernest Allen, Seattle, WA (US); Andrew E. Horch, Seattle, WA (US); Robert C. Collins, Seattle, WA (US)

Correspondence Address: SCHWEGMAN, LUNDBERG, WOESSNER & KLUTH/IMPINJ, PO BOX 2938, MINNEAPOLIS, MN, 55402, US

(21) Appl. No.: 11/470,526

(22) Filed: Sep. 6, 2006

Related U.S. Application Data
(60) Provisional application No. 60/783,447, filed on Mar. 17, 2006.

(51) Int. Cl. G01R 31/28; H01R 43/00; H04Q 5/22; G08B 13/14

(52) U.S. Cl. 29/593; 29/825; 340/572.1; 340/10.1

(57) ABSTRACT

A chip has formed thereon integrated circuit elements, which include a main circuit and an associated non volatile memory structure. A test result associated with prior testing of a function of the main circuit is stored in the non volatile memory structure. Additional apparatus and methods are disclosed.

### PRIORITY CLAIM

This application claims the benefit of priority to U.S. Provisional Patent Application Ser. No. 60/783,447, filed Mar. 17, 2006, which is incorporated herein by reference.

### TECHNICAL FIELD

The information in this document is related to electronic circuitry testing, including apparatus, systems, and methods that enable the communication of circuit test results.

### BACKGROUND INFORMATION

Radio frequency identification (RFID) systems may include RFID tags and RFID readers (the latter may also be known as RFID reader/writers or RFID interrogators). RFID systems can be used in many ways, including locating and identifying objects to which the tags are attached. RFID systems are particularly useful in product-related and service-related industries for tracking large numbers of objects being processed, inventoried, or handled. In such cases, an RFID tag is usually attached to an individual item, or to its package.

In principle, RFID techniques entail using an RFID reader to interrogate one or more RFID tags. The reader transmitting a Radio Frequency (RF) wave performs the interrogation. A tag that senses the interrogating RF wave responds by transmitting back another RF wave. The tag generates the transmitted back RF wave either originally, or by reflecting back a portion of the interrogating RF wave in a process known as backscatter. Backscatter may take place in a number of ways.

The reflected-back RF wave may further encode data stored internally in the tag, such as a number. The response may be demodulated and decoded by the reader, which thereby identifies, counts, or otherwise interacts with the associated item.

An RFID tag typically includes an antenna system, a power management section, a radio section, and frequently a logic section, a memory, or both. In earlier RFID tags, the power management section included an energy storage device, such as a battery. RFID tags with such an energy storage device are known as active tags. Advances in semiconductor technology have miniaturized the electronics so much that many RFID tags can be powered solely by the received RF signal. Such RFID tags do not include an energy storage device, and are called passive tags.

Electronic circuitry manufacturers, including RFID tag manufacturers, are interested in purchasing circuitry that has a high probability of operating correctly after assembly, with minimal testing, and so prior to purchase, the results of testing circuitry on a wafer may be provided to the manufacturer as a map file, associating the test results with the location of particular circuitry on the wafer. However, when the wafer is diced to form chips, the individual chips may be shuffled, and the testing results become lost. Thus, there is a need for improved mechanisms to track the results of circuitry-on-wafer testing.

### BRIEF DESCRIPTION OF THE DRAWINGS

FIG. 1 is a block diagram of components of an RFID system, according to various embodiments of the invention.

FIG. 2 is a diagram showing components of a passive RFID tag, including a tag that can be used in the system of FIG. 1, according to various embodiments of the invention.

FIG. 3 is a conceptual diagram illustrating a half-duplex mode of communication between the components of the RFID system of FIG. 1, according to various embodiments of the invention.

FIG. 4 is a flowchart illustrating testing methods according to various embodiments of the invention.

FIG. 5 is a diagram of a wafer having integrated circuit elements formed and tested according to the methods of the flowchart of FIG. 4.

FIG. 6 is a block diagram of integrated circuit elements that can be formed as one or more integrated circuits on the wafer of FIG. 5, according to various embodiments of the invention.

FIG. 7 is a block diagram of an electrical circuit according to some embodiments of FIG. 5, including an RFID tag, and a non volatile memory structure.

FIG. 8 is a diagram illustrating a scheme for storing test results according to various embodiments of the invention.

FIG. 9 is a conceptual diagram illustrating separation of the wafer of FIG. 5 into multiple integrated circuit (IC) chips.

FIG. 10 is a block diagram of an integrated circuit chip shown in FIG. 9, and further showing various embodiments.

FIG. 11 is a flowchart illustrating methods of processing chips, such as those of FIG. 9, according to various embodiments of the invention.

FIG. 12 is a conceptual diagram illustrating a sample processing activity according to embodiments of the methods of FIG. 11.

FIG. 13 is a conceptual diagram illustrating IC chip sorting according to embodiments of the methods of FIG. 11.

FIG. 14 is a conceptual diagram to illustrate sorting RFID IC chips that can be at least partly assembled into RFID tags such as those of FIG. 12 according to embodiments of the method of FIG. 11.

### DETAILED DESCRIPTION

Many of the embodiments disclosed herein are related to testing electronic circuitry provided in the form of integrated circuits. For example, the challenges noted above may be addressed by storing integrated circuit test results in a non volatile memory associated with the tested circuit (e.g., the tested circuit and non volatile memory may be included on the same chip or wafer). In some embodiments, circuit testing and storage of the test results may be accomplished before chips are separated from a common wafer. The tested circuitry may be used in many applications, including RFID, as elaborated in more detail below for purposes of illustration, but not limitation.

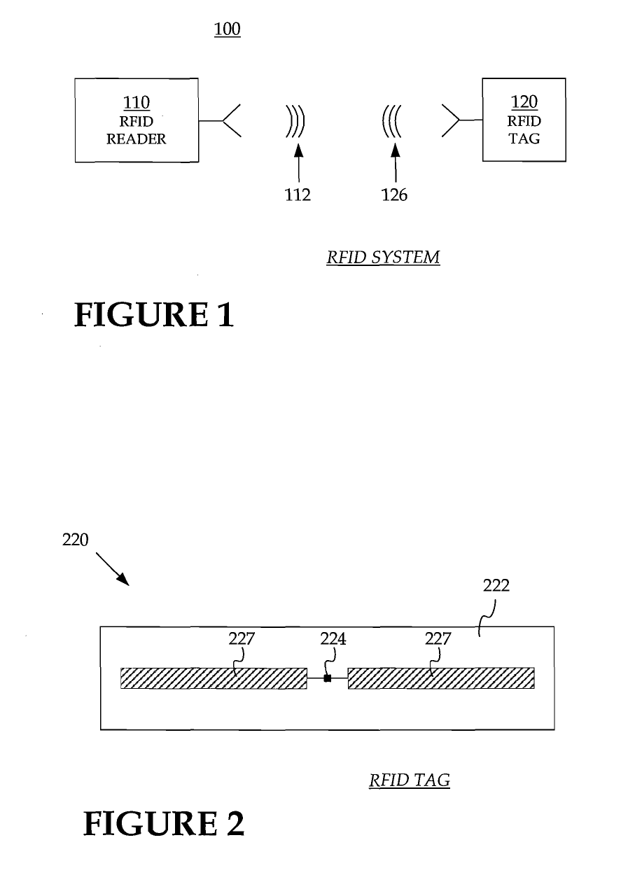

FIG. 1 is a block diagram of components in an RFID system 100, according to various embodiments of the invention. An RFID reader 110 transmits an interrogating Radio Frequency (RF) wave 112. The RFID tag 120 in the vicinity of the RFID reader 110 may sense the interrogating RF wave 112, and generate a wave 126 (e.g., via direct transmission or backscatter) in response. The RFID reader 110 may then sense and interpret the wave 126.

Reader 110 and tag 120 may exchange data via the wave 112 and the wave 126. In a session of such an exchange, each may encode, modulate, and transmit data to the other, and each may receive, demodulate, and decode data from the other. The data is modulated onto, and decoded from, RF waveforms 112, 126.

Encoding the data in waveforms can be performed in a number of different ways. For example, protocols may be devised to communicate in terms of symbols, also called RFID symbols. A symbol for communicating may comprise a delimiter, a calibration symbol, and so on. Additional symbols can be implemented for ultimately exchanging binary data, such as “0” and “1”, if that is desired. In turn, when the waveforms are processed internally by the reader 110 and the tag 120, they can be equivalently considered and treated as numbers having corresponding values.

The tag 120 can be a passive tag or an active tag, i.e. having its own power source. Where tag 120 is a passive tag, it may be powered from wave 112.

FIG. 2 is a diagram of an RFID tag 220, which can be the same as tag 120 of FIG. 1. Tag 220 is implemented as a passive tag, meaning it does not have its own power source. Much of what is described in this document, however, applies also to active tags.

Tag 220 is formed on a substantially planar inlay 222, which can be made in many ways known in the art. Tag 220 also includes two antenna segments 227, which are usually flat and attached to inlay 222. Antenna segments 227 are shown here forming a dipole, but many other embodiments using any number of antenna segments are possible.

Tag 220 also includes an electrical circuit, which is preferably implemented as an integrated circuit (IC) 224. IC 224 is also arranged on inlay 222, and electrically coupled to the antenna segments 227. While one method of coupling is shown, many are possible.

In operation, a signal is received by antenna segments 227, and communicated to IC 224. IC 224 both harvests power, and responds if appropriate, based on the incoming signal and its own internal state. In order to respond by replying, IC 224 can modulate the reflectance of antenna segments 227, which generates backscatter from a wave originally transmitted by the reader. Coupling together and uncoupling antenna segments 227 can modulate the reflectance, as can a variety of other means.

In the embodiment of FIG. 2, antenna segments 227 are separate from IC 224. In other embodiments, the antenna segments 227 may be formed on IC 224.

The components of the RFID system 100 of FIG. 1 may communicate with each other in any number of modes. One such mode is called full duplex. Another such mode is called half-duplex, and is described below.

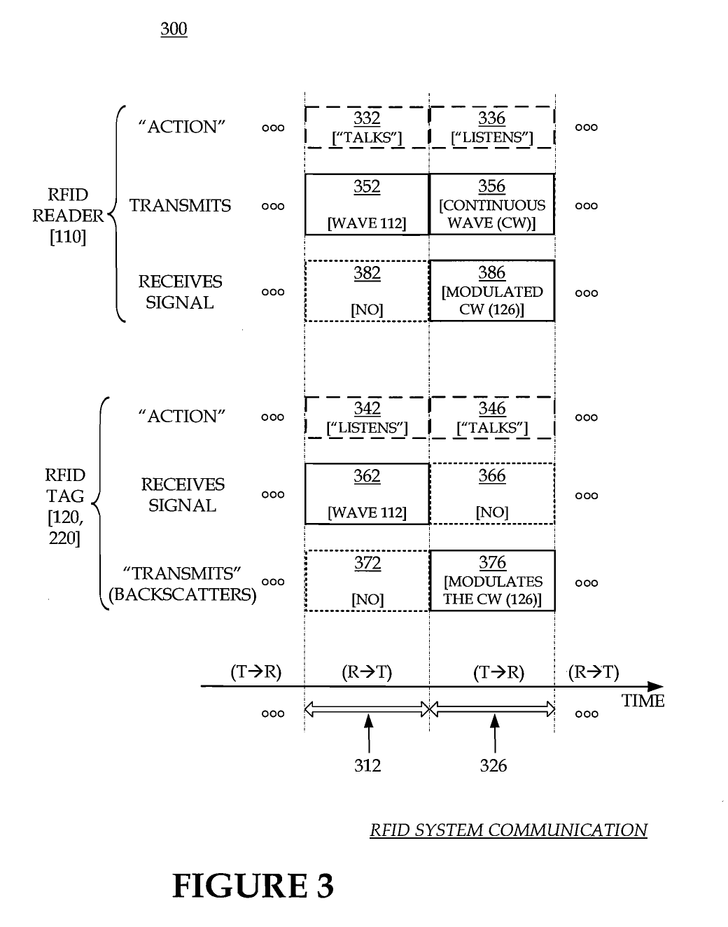

FIG. 3 is a conceptual diagram 300 illustrating a half-duplex mode of communication between the components of the RFID system 100 of FIG. 1, according to various embodiments of the invention, including when the tag 120 is implemented as a passive tag 220 of FIG. 2. The following explanation is made with reference to a TIME axis, and also to a human metaphor of “talking” and “listening”. The actual technical implementations of “talking” and “listening” are now described.

The RFID reader 110 and the RFID tag 120 talk and listen to each other by taking turns. As seen on the TIME axis, when the reader 110 talks to the tag 120, the communication session is designated as “R→T”, and when the tag 120 talks to the reader 110, the communication session is designated as “T→R”. Along the TIME axis, a sample R→T communication session may occur during a time interval 312, and a follow-on sample T→R communication session may occur during a time interval 326. Of course, the intervals 312, 326 can be of different durations—here the durations are shown approximately equal only for purposes of illustration, and the various embodiments are not to be so limited.

According to blocks 332 and 336, the RFID reader 110 talks during interval 312, and listens during interval 326. According to blocks 342 and 346, the RFID tag 120 listens while reader 110 talks (during interval 312), and talks while the reader 110 listens (during interval 326).

In terms of actual technical behavior, during the interval 312, the reader 110 talks to the tag 120 as follows. According to block 352, the reader 110 transmits the wave 112, which was first described in FIG. 1. After a relatively short delay determined by the wave 112 propagation time from the reader 110 to the tag 120, according to block 362, the tag 120 receives the wave 112 and processes it as required. Meanwhile, according to block 372, the tag 120 does not operate to backscatter the wave 112 with its antenna, and according to block 382, the reader 110 therefore has no wave 126 to receive from tag 120.

During the interval 326, the tag 120 talks to the reader 110 as follows. According to block 356, the reader 110 transmits a signal, which may comprise a continuous wave (CW) signal, which can be thought of as a carrier signal that ideally encodes no information. As discussed before, this carrier signal may serve both to be harvested by the tag 120 for its own internal power needs, and also as a wave that tag 120 can backscatter. Indeed, during interval 326, according to block 366, the tag 120 does not receive a signal for processing. Instead, according to block 376, the tag 120 operates to modulate the CW signal emitted according to block 356, so as to generate a backscatter wave 126. Thereafter, according to block 386, the reader 110 receives backscatter wave 126 and processes it.

In some embodiments, an RFID reader/interrogator may communicate with one or more RFID tags in any number of ways. Some of these ways are defined by protocols. A protocol is a specification that calls for a specific manner of signaling between the reader and the tags. For example, one such protocol is entitled “EPC™ Radio-Frequency Identity Protocols Class-1 Generation-2 UHF RFID Protocol for Communications at 860 MHz-960 MHz,” EPC Global Inc., Version 1.0.9, January 2005, and is incorporated herein by reference in its entirety. This protocol is also colloquially known as “the Gen2 Spec”.

It has been described above how the reader 110 and the tag 120 may communicate in terms of time. In addition, communications between the reader 110 and the tag 120 may be described in terms of frequency. For example, frequency restrictions may be imposed so that the available frequency spectrum is partitioned into divisions that are called channels. Different partitioning schemes may be specified by the various regulatory jurisdictions and authorities (e.g., the Federal Communications Commission (FCC) in North America, the Conférence Européenne des Administrations des Postes et des Télecommunications (CEPT) in Europe, etc.).

The reader 110 may transmit using a transmission spectrum that lies within one channel, or using multiple channels. In some regulatory jurisdictions the authorities permit aggregating multiple channels into one or more larger channels, but for all practical purposes an aggregate channel can again be considered a single, albeit larger, individual channel.

Tag 120 can respond with a backscatter signal 126 that is modulated directly onto the frequency of the reader's emitted CW signal 112, sometimes called baseband backscatter. Alternatively, the tag 120 can respond with a backscatter signal 126 that is modulated onto a frequency, developed by the tag 120, that is different from the reader's emitted CW signal 112, and this modulated tag frequency may then be impressed upon the reader's emitted CW signal 112. This second type of backscatter operation is sometimes called subcarrier backscatter. The subcarrier frequency can be within the reader's channel, can straddle the boundaries of the reader's channel and an adjacent channel, or can be wholly outside the reader's channel.

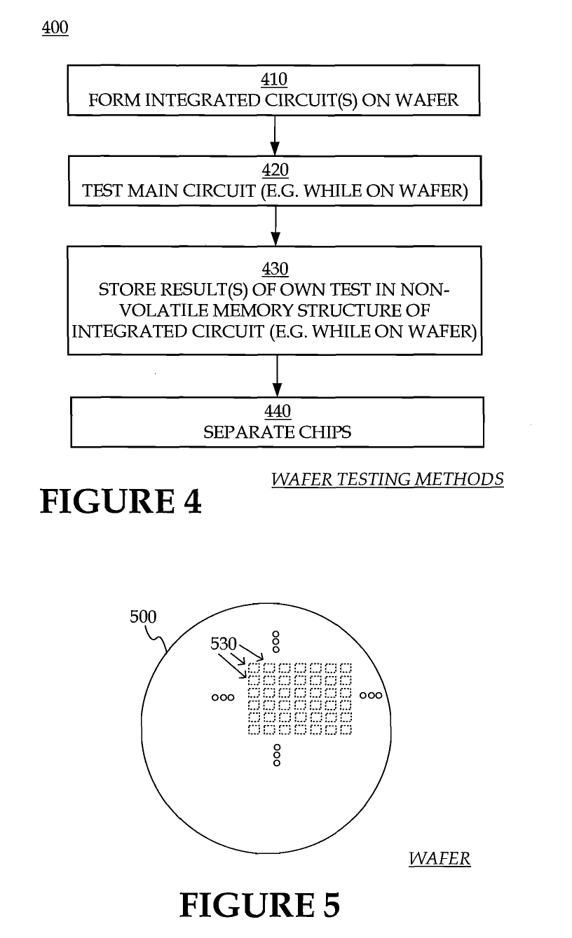

FIG. 4 is a flowchart illustrating testing methods 400 according to various embodiments of the invention, and FIG. 5 is a diagram of a wafer 500 having integrated circuit elements 530 that may be formed and tested according to methods of the flowchart of FIG. 4. From these figures, it can be seen that many embodiments may be realized.

For example, as can be seen in FIG. 4, a method 400 may include forming, on a wafer, integrated circuit elements at block 410. The integrated circuit elements may include any number of items, including a main circuit and a non volatile memory structure associated with the main circuit. The wafer may be similar to or identical to the wafer 500 of FIG. 5, and the integrated circuit elements may be similar to or identical to the circuit elements 530 formed on the wafer 500 of FIG. 5.

Referring back to FIG. 4, the method 400 may include testing a function of the main circuit at block 420, and storing a test result associated with the testing activity of block 420 in the non volatile memory structure at block 430. Tested functions may include processing speed, memory storage and recall speed, repeatability of operations, reliability over temperature, as well as many others. The testing can happen at different nodes of production.

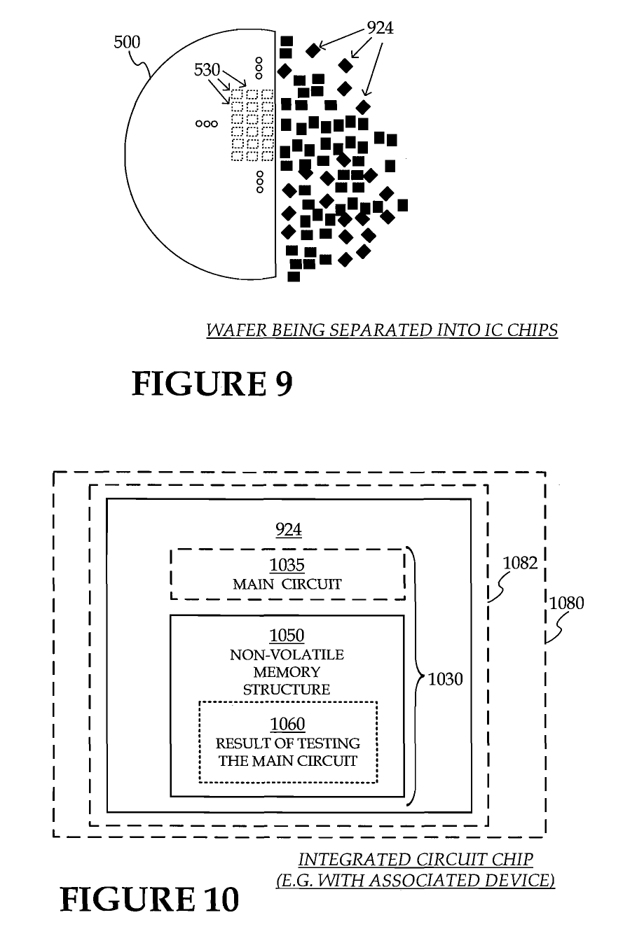

In some embodiments, the method 400 may include separating a chip that includes one or more of the integrated circuit elements from the remainder of the wafer at block 440 (see description of FIG. 9 below). Since the activities of the method 400 may be performed in any order, in some embodiments the storing activity of block 430 is performed before the separating activity of block 440. In some embodiments, the storing activity of block 430 is performed after the separating activity of block 440. The testing activity of block 420 and/or the storing activity of block 430 may be accomplished by physically probing the chip and/or directing radio frequency energy at the chip, before or after the chip is separated from the wafer.

The main circuit may comprise any number of circuits, including RFID circuits. The main circuit may be associated with an on-chip antenna after the separating activity of block 440, and storing the test result at block 430 may include transmitting a signal that is received by the on-chip antenna.

The non volatile memory structure may also comprise a variety of circuit element types, including one or more fuses, perhaps comprising one-time programmable fuses and/or many-times programmable fuses.

The non volatile memory structure may be used to store any number of items, including a product code associated with the circuit. This is most applicable when the circuit is an RFID circuit, in which case the memory structure can also or alternately include user memory, TID, and so on.

Such a product code may comprise a code describing an item to which the RFID circuit is already attached, or to which the RFID circuit is to be attached, for example. Such product codes may thus include electronic product codes (EPCs), known to those of ordinary skill in the art. In some embodiments, the product code may comprise a code describing one or more characteristics of an item to which the RFID circuit is attached, or to which the RFID circuit is to be attached. In some embodiments, the test result may even comprise, or consist of, the product code associated with the RFID circuit.

The storing activity of block 430 may occur under a variety of conditions. For example, in some embodiments, the storing activity of block 430 may be performed only if the tested function has passed the test(s) imposed during the testing activity of block 420. Similarly, the storing activity of block 430 may be performed only if the tested function has failed one or more tests imposed during the testing activity of block 420.

The content of the non volatile memory structure may be protected from access. For example, in some embodiments, the non volatile memory cannot be read by the main circuit. In other embodiments, the content of the non volatile memory structure can be read by the main circuit.

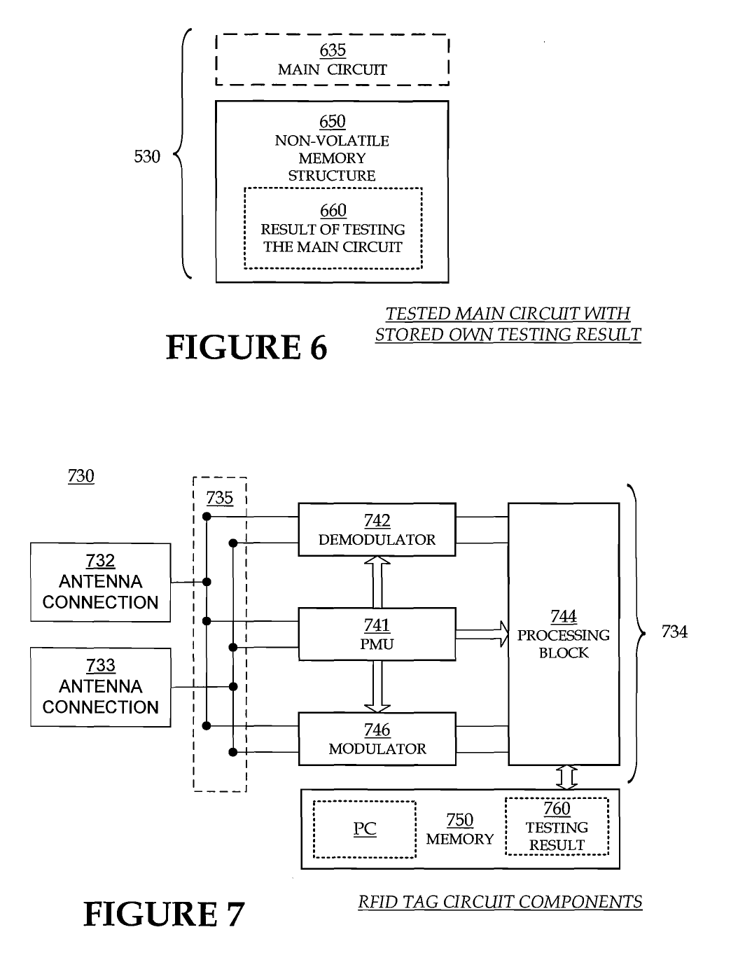

FIG. 6 is a block diagram of integrated circuit elements 530 that can be formed as one or more integrated circuits on the wafer 500 of FIG. 5, according to various embodiments of the invention. Here it can be seen that the main circuit 635 may be formed together with the non volatile memory structure 650 as a single integrated circuit element 530. In some embodiments, the main circuit 635 may be formed separately from the non volatile memory structure 650, as separate integrated circuit elements 530. The main circuit 635 may comprise a microprocessor, a memory, combinations thereof, and other circuitry, both digital and analog. Thus many embodiments may be realized.

FIG. 7 is a block diagram of an electrical circuit 730 according to some embodiments of FIG. 5 (e.g., similar to or identical to the circuit 530 of FIG. 5), including an RFID tag, and a non volatile memory structure 750. The circuit 730 may be formed as an IC of an RFID tag, such as IC 224 of FIG. 2. The circuit 730 may have a number of components that are described in this document, such as a main circuit 734 (similar to or identical to the main circuit 635 of FIG. 6, described above), and the memory 750 (similar to or identical to the memory 650 of FIG. 6, described above). The circuit 730 may also have a number of additional components from what is shown and described in FIG. 7, or different components, depending on the particular implementation.

The circuit 730 includes one or more antenna connections 732, 733, which are suitable for coupling to one or more antenna segments (not shown in FIG. 7, but may be similar to or identical to the antenna segments 227 of FIG. 2). Antenna connections 732, 733 may be made in any suitable way, perhaps comprising pads, and so on. In a number of embodiments more than two antenna connections are used, generally in embodiments where additional antenna segments are used.

The circuit 730 may include a section 735, which may be implemented as a group of nodes 736 for routing signals. In some embodiments, the section 735 may be implemented otherwise, for example to include one or more receive/transmit switches that can route signals, and so on.

The circuit 730 also includes a power management unit (PMU) 741. The PMU 741 may be implemented in any way known in the art, for harvesting raw RF power received via the antenna connections 732, 733. In some embodiments, the PMU 741 includes at least one rectifier, and so on.

In operation, an RF wave received via the antenna connections 732, 733 is received by the PMU 741, which in turn generates power for various components of the circuit 730. This is true for either or both R→T sessions and T→R sessions, whether or not the received RF wave is modulated.

The circuit 730 additionally includes a demodulator 742 that operates to demodulate an RF signal received via the antenna connections 732, 733. The demodulator 742 may be implemented in any way known in the art, for example, including an attenuator stage, an amplifier stage, and so on.

The circuit 730 further includes a processing block 744 that operates to receive the demodulated signal from the demodulator 742, and may perform operations on the information obtained from the demodulated signal. In addition, the processing block 744 may generate an output signal for transmission.

The processing block 744 may be implemented in any way known in the art. In some embodiments, the processing block 744 may include a number of components, such as a digital tag controller, a memory, a decoder, an encoder, and so on.

The circuit 730 additionally includes a modulator 746 that operates to modulate an output signal generated by the processing block 744. The modulated signal may be transmitted by driving the antenna connections 732, 733, thereby driving the load presented by the subsequently coupled antenna segment or segments. The modulator 746 may be implemented in any way known in the art, for example, including a driver stage, an amplifier stage, and so on.

In some embodiments, the demodulator 742 and the modulator 746 may be combined in a single transceiver circuit. In some embodiments, the modulator 746 may include a backscatter transmitter or an active transmitter. In yet other embodiments, the demodulator 742 and the modulator 746 may form part of the processing block 744.

It will be recognized at this juncture that the circuit 730 can also comprise a portion of an RFID reader according to various embodiments of the invention, without needing the PMU 741. Indeed, an RFID reader can be powered differently, such as from a wall outlet, a battery, and so on. Additionally, when the circuit 730 is configured as a reader, the processing block 744 may have additional inputs/outputs (I/Os) to a terminal, network, and other such devices or connections.

In terms of processing a signal, the circuit 730 operates differently during a R→T session and a T→R session. The different operations have been described above. Thus, many additional embodiments may be realized.

For example, referring now to FIGS. 5, 6, and 7, it can be seen that some embodiments include a wafer 500 having formed thereon integrated circuit elements 530, which comprise a main circuit 635 and a non volatile memory structure 650 associated with the main circuit 635. The non volatile memory structure 650 may have stored therein one or more test results 660 associated with prior testing of one or more corresponding functions of the main circuit 635. As noted above, the non volatile memory structure 650 may also comprise a variety of circuit element types, such as one or more fuses, perhaps comprising one-time programmable fuses and/or many-times programmable fuses.

The non volatile memory structures 650, 750 may be used to store any number of items, including a product code PC associated with the main circuit 635, such as an RFID circuit 734. Thus, the product code PC may comprise a code describing an item and/or one or more characteristics of an item to which the RFID circuit 734 is attached, or to which the RFID circuit 734 is to be attached at some later time. Such product codes PC may include electronic product codes (EPCs), known to those of ordinary skill in the art. In some embodiments, the test result 760 may even comprise, or consist of, the product code PC associated with the RFID circuit 734.

As noted above, storing test results into the non volatile memory structure 650, 750 may occur under a variety of conditions. For example, in some embodiments, storing may be performed only if the tested function of the main circuit 735 has passed the test(s) imposed during the testing activity. Similarly, in some embodiments, storing may be performed only if the tested function has failed one or more tests imposed during the testing activity.

In many embodiments, the content of the non volatile memory structure 650, 750 may be protected from access. For example, in some embodiments, the non volatile memory 650 cannot be read by the main circuit 635. In some embodiments, the content 660 of the non volatile memory structure 650 can be read by the main circuit 635.

The integrated circuit elements 530 may include multiple main circuits 635 and multiple non volatile memory structures 650, perhaps formed as substantial duplicates of each other. In some embodiments, the non volatile memory structures 650 are formed in a one-to-one correspondence with the main circuits 635. In some embodiments, a single non volatile memory structure 650 may be formed and associated with multiple main circuits 635. Thus, in some cases, test results 660 for only one main circuit 635 may be stored in a single non volatile memory structure 650. In others, multiple test results for multiple main circuits 635 may be stored in a single non volatile memory structure 650.

As noted above, the integrated circuit elements 530 may be similar to or identical to the integrated circuit 224 shown in FIG. 2. Thus, one or more on-chip antennas may be associated with the main circuit 635.

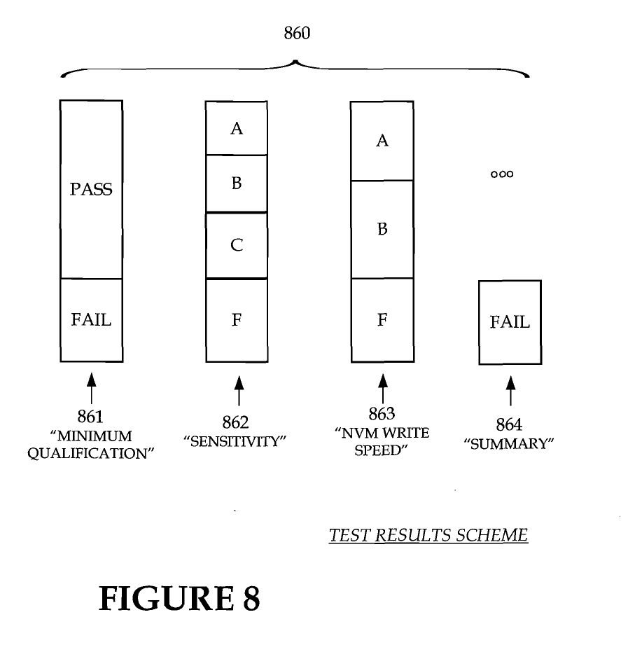

FIG. 8 is a diagram illustrating a scheme for storing test results according to various embodiments of the invention. In many embodiments, the test results may be stored in a non volatile memory structure 860, which may be similar to or identical to the structure 750 of FIG. 7.

Test results may be stored in a variety of ways. For example, the test result may include passed results (e.g., some character, number, or physical condition stored in the non volatile memory structure indicating “PASS”, “GOOD”, “1”, etc.); failed results(e.g., some character, number, or physical condition stored in the non volatile memory structure indicating “FAIL”, “BAD”, “0”, etc.); and/or grades (some character, number, or physical condition stored in the non volatile memory structure indicating a degree of performance or capability, such as “A”, “B”, . . . , “F”; “10%”, . . . , “70%”, . . . , “100%”; “MINIMAL”, “AVERAGE”, “PREMIUM”, etc.).

In addition, storing test results (e.g., the storing activity of block 430 in FIG. 4) may include storing at least a part of the test result as a plurality of individual results corresponding to a plurality of individual tests. Thus, as seen in FIG. 8, the results “PASS” for the MINIMUM QUALIFICATION test, “A” for the SENSITIVITY test, and “F” for the NVM WRITE SPEED test may all be stored separately in the structure 860. Some test results may also be excluded. Thus, the stored test result may comprise a passed result, and exclude a failed result. In some embodiments, the stored test result may comprise a failed result, and exclude a passed result.

In some embodiments, storing test results (e.g., the storing activity of block 430 in FIG. 4) may include storing at least a part of the test result as an aggregate result of multiple tests. Thus, as seen in FIG. 8, “FAIL” may be stored as an aggregate result in the structure 860 to indicate a SUMMARY result (e.g., the designer of the embodiment might choose to store an aggregate “FAIL” test result 864 if any of the individual tests results 861, 862, 863 indicate failure). In some cases only aggregate results 864 may be stored. In others, both aggregate results 864 and individual results 861, 862, 863 maybe stored.

Other embodiments might include grouping only the SENSITIVITY test result and the NVM WRITE SPEED test results together into the SUMMARY test result, so that a failing MINIMUM QUALIFICATION may not have an effect on the SUMMARY test result. Such varied grouping may be used to select parts for various bins, for example, as will be discussed below.

FIG. 9 is a conceptual diagram illustrating separation of the wafer 500 of FIG. 5 into multiple integrated circuit (IC) chips 924. Each chip 924 may include one or more integrated circuit elements 530. It should be noted that the testing and storing activities described above may be accomplished either before the chips 924 have been separated from the wafer 500, or after separation.

FIG. 10 is a block diagram of an integrated circuit chip 924 shown in FIG. 9. Chip 924 includes circuit elements 1030 analogous or similar to circuit elements 530 of FIG. 6. These include a main circuit 1035 analogous or similar to circuit 635, and a non volatile memory structure 1050 analogous or similar to structure 650. A test result 1060 is stored in memory structure 1050, from prior testing of main circuit 1035, similarly to what was described above for test result 660.

Many additional optional embodiments may be realized. For example, a device 1080 (e.g., a digital video disk sales package or multi-media player, a laptop computer, a cell phone, etc.) may include one or more chips 924 having formed thereon integrated circuit elements 1030, which include a main circuit 1035 and one or more associated non volatile memory structures 1050 having test results 1060 stored therein.

In some embodiments, the chip 924 may be attached to a base 1082. The base may comprise a carrier, a strap, or an inlay, as are known to those of ordinary skill in the art. For example, an RFID tag may be formed.

Since the chip 924 may be the same as the chip 224 of FIG. 2, an antenna may be coupled to the chip 924, and located off- or on-chip. The antenna may be used to receive the test result 1060 in a signal prior to the test result being stored in the non volatile memory structure 1050 in some embodiments. Various methods of processing the chips 924 may also be realized.

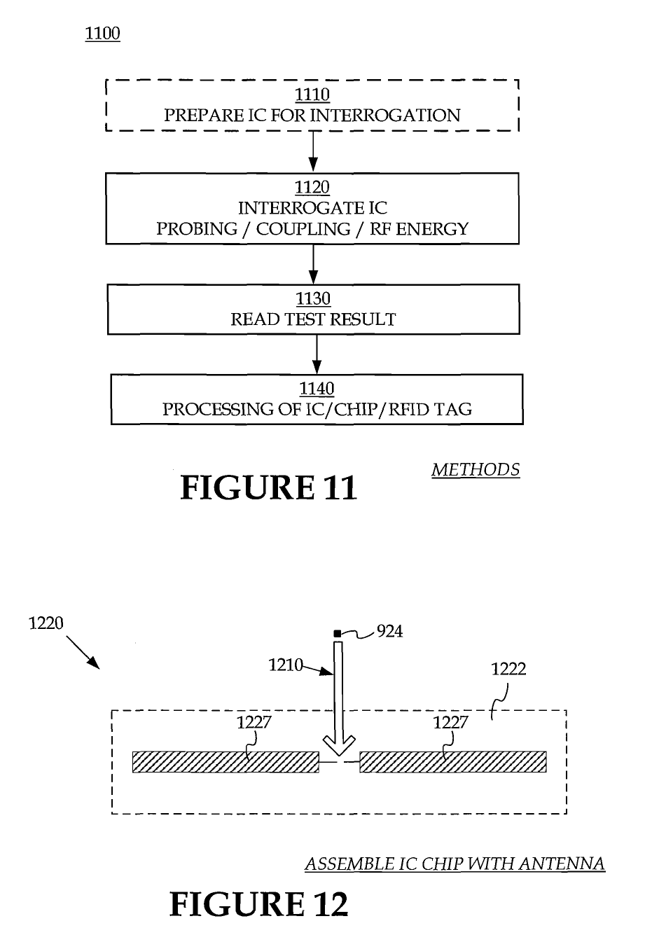

FIG. 11 is a flowchart illustrating methods 1100 of processing chips, such as those of FIG. 9, according to various embodiments of the invention. For example, a method 1100 may include at block 1110 preparing a wafer, chip, and/or integrated circuit element for interrogation so that test results may be obtained. Thus, as part of preparing the chip, block 1110 may include preparing a chip having formed thereon integrated circuit elements including a main circuit and a non volatile memory structure. In some embodiments, the chip is prepared by being separated from the remainder of a wafer.

FIG. 12 is a conceptual diagram illustrating a sample processing activity according to embodiments of the methods 1100 of FIG. 11. For example, the chip 924 may be prepared for interrogation by placing the chip 924 on a base 1222, such as a carrier, strap, or inlay. The chip 924 may be further prepared by attaching an antenna (e.g., one or more antenna segments 1227) to the chip 924 to receive radio frequency energy 1210. Other preparation activities may include assembling the chip 924 into an RFID tag 1220, perhaps by assembling the chip into an RFID tag using a mass fluidic orientation and assembly technique. For more information regarding such techniques, the reader is referred to “Fluidic Self-Assembly of Silicon Microstructures,” A. K. Verma, et al., Electronic Components and Technology Conference, 1995, and similar literature.

Referring back to FIG. 11, it can be seen that in some embodiments, the method 1100 may include interrogating the chip to provide the stored test result for reading at block 1120. Interrogating may be accomplished in many ways. For example, interrogating at block 1120 may include probing the chip. Interrogating may also include coupling interrogation circuitry to the chip, and sending, from the interrogation circuitry to the chip, a request to retrieve one or more stored test results. Interrogation may also be accomplished using a wireless mechanism, such as by directing radio frequency energy at the chip, and receiving backscattered energy from the chip (perhaps using an on-chip antenna) that encodes the stored test result.

In some embodiments, the method 1100 may include reading from the non volatile memory structure a stored test result associated with prior testing of a function of the main circuit at block 1130. Reading may be accomplished in a variety of ways. For example, block 1130 may include reading the stored test result as a plurality of individual results corresponding to a plurality of individual tests, or reading the stored test result one or more aggregate results of multiple tests.

In some embodiments, the method 1100 may include processing the chip according to the stored test result at block 1140. Processing may include many different variations and aspects. For example, processing may include discarding the chip if reading the stored test result fails, or if the stored test result comprises a failed result. Similarly, processing may include retaining the chip only if the stored test result comprises a passed result.

In some embodiments, processing further includes rendering the test result unreadable, so it is unavailable for further reading. One such way is to delete it, another to scramble it, and so on.

Processing at block 1140 may also include segregation. For example, processing at block 1140 may include segregating, from a plurality of chips, those chips whose stored test result comprises a passed result, or a failed result, or both. Other variations may include, for example, including a grade in the stored test result, and retaining the chips that are associated with the same grade.

In some embodiments, the test result may comprise a product code associated with the RFID circuit, and may be used to separate the chip into a bin for that particular product code. Of course, the test result comprising a product code may also be associated with a device to which the RFID circuit is already attached, or to which the RFID circuit is to be attached at some later time.

Processing at block 1140 may include additional activities, such as attaching an antenna to the chip, and/or creating an RFID tag using the chip. The processing at block 1140 may also include assembling the chip into an RFID tag using a mass fluidic orientation and assembly technique.

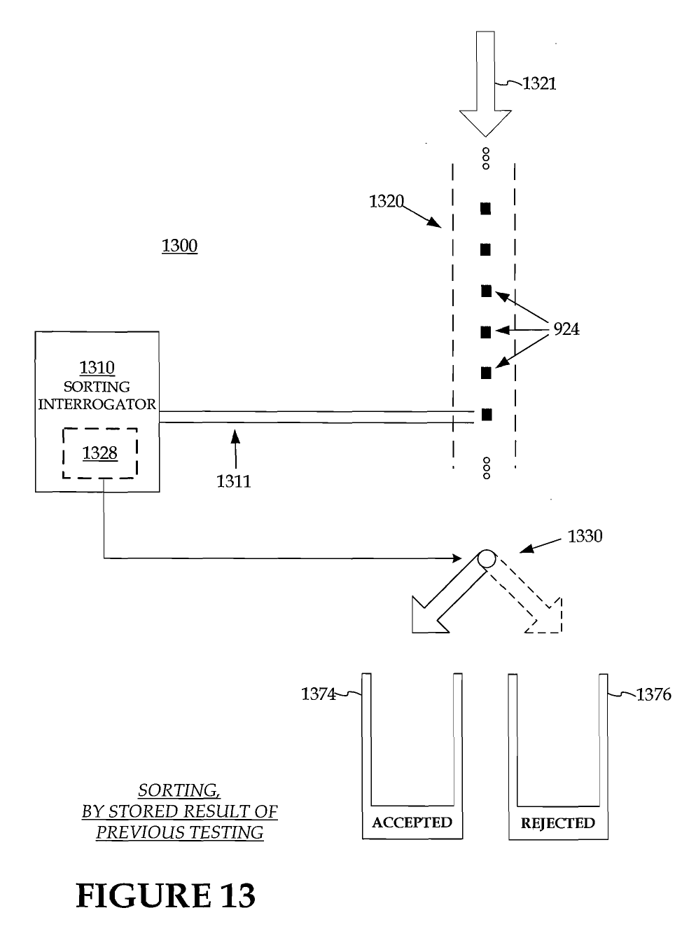

FIG. 13 is a conceptual diagram illustrating IC chip sorting according to embodiments of the methods of FIG. 11. Here a system 1300 can be used to process chips 924, perhaps carried on a conveyor 1320, according to the stored test results, as described above. Interrogation and reading may be accomplished using a wireless connection 1321 (e.g., RF interrogation via backscatter), or a wired connection 1311 (e.g., interrogation via probing). A sorting interrogator 1310 may include sorting logic 1328 to receive one or more test results from the chips 924 via interrogation, and operate a sorting mechanism 1330 to distribute the chips 924 into an accepted bin 1374 and a rejected bin 1376, for example.

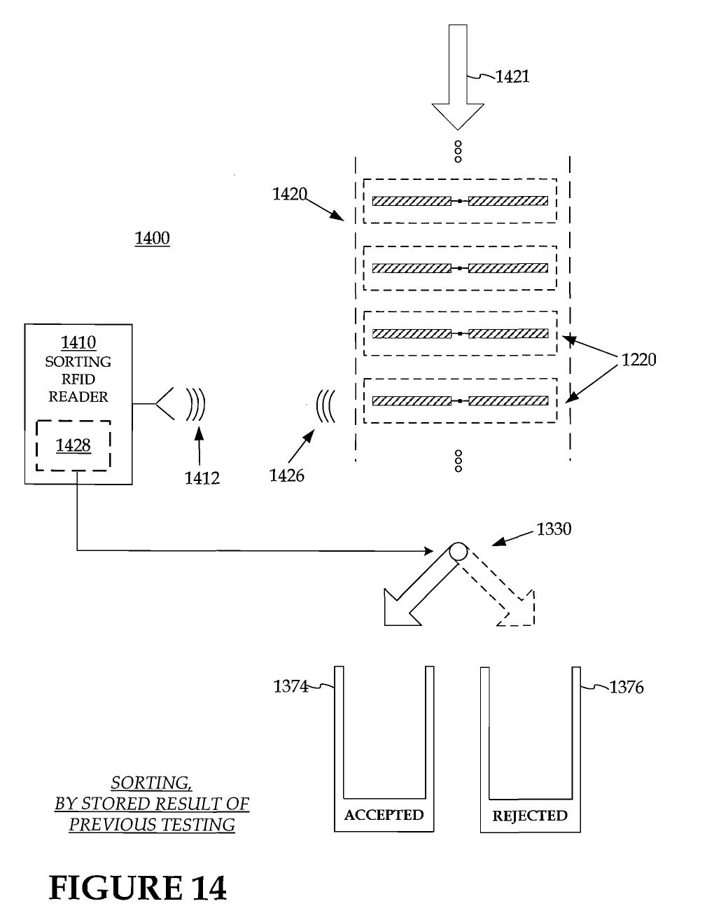

FIG. 14 is a conceptual diagram to illustrate sorting RFID IC chips that may be partly assembled into RFID tags such as the tag 1220 of FIG. 12 according to embodiments of the method of FIG. 11. Here a system 1400 can be used to process the tags 1220, perhaps carried on a conveyor 1420, according to the stored test results, as described above. Interrogation and reading may be accomplished using a wireless connection, including signals 1412 and 1426, corresponding to the signals 112, 126 of FIG. 1, respectively. A sorting RFID reader 1410 may include sorting logic 1428 to receive one or more test results 1428 from the tags 1220 via interrogation (e.g., talking and listening as described with respect to FIG. 3 above), and operate a sorting mechanism 1330 to distribute the tags 1220 into an accepted bin 1374 and a rejected bin 1376, for example.

It should be noted that the methods described herein can be implemented in any number of ways, including via the structures described in this document. One such way is by machine operations, using devices of the type described in this document. Another optional way is for one or more of the individual operations of the methods to be performed in conjunction with one or more human operators performing others. These human operators need not be collocated with each other, but each may be located separately, along with one or more machines that perform a portion of the operations described.

In addition, it should be noted that the methods described herein do not have to be executed in the order described, or in any particular order. Moreover, various activities described with respect to the methods identified herein can be executed in iterative, repetitive, serial, or parallel fashion. Information, including parameters, commands, operands, and other data, can be sent and received in the form of one or more carrier waves.

Upon reading and comprehending the content of this disclosure, one of ordinary skill in the art will understand the manner in which a software program can be launched from a computer-readable medium in a computer-based system to execute the functions defined in the software program. One of ordinary skill in the art will further understand the various programming languages that may be employed to create one or more software programs designed to implement and perform the methods disclosed herein. The programs may be structured in an object-orientated format using an object-oriented language such as Java or C++. Alternatively, the programs can be structured in a procedure-orientated format using a procedural language, such as assembly or C. The software components may communicate using any of a number of mechanisms well known to those skilled in the art, such as application program interfaces or interprocess communication techniques, including remote procedure calls. The teachings of various embodiments are not limited to any particular programming language or environment.

Thus, other embodiments may be realized. For example, an article of manufacture according to various embodiments, such as a computer, a memory system, a magnetic or optical disk, some other storage device, an RFID reader, an RFID tag, and/or any type of electronic device or system may include a processor coupled to a machine-accessible medium such as a memory (e.g., removable storage media, as well as any memory including an electrical, optical, or electromagnetic conductor) having associated information (e.g., computer program instructions and/or data), which when accessed, results in a machine (e.g., the processor) performing any of the actions described with respect to the methods above.

Using the circuits and methods disclosed herein may provide an improved mechanism for tracking the results of testing chips. For example, having non volatile memory structures to record testing results for closely-associated circuits may provide greater flexibility with respect to when and where testing occurs, as well as to what can be done with the testing results.

The accompanying drawings that form a part hereof, show by way of illustration, and not of limitation, specific embodiments in which the subject matter may be practiced. The architecture of the system is presented for purposes of explanation, and not of limitation. Its particular subdivision into modules need not be followed for creating embodiments according to the invention. Furthermore, the features of the invention can be performed either within a single one of the modules, or by a combination of them. An economy is achieved by using a single set of flowcharts to describe methods in and of themselves, along with operations of hardware and/or software. This is regardless of how each element is implemented.

The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

In this description, numerous specific details such as logic implementations, opcodes, means to specify operands, resource partitioning, sharing, and duplication implementations, types and interrelationships of system components, and logic partitioning/integration choices are set forth in order to provide a more thorough understanding of various embodiments. It will be appreciated, however, by those skilled in the art that embodiments of the invention may be practiced without such specific details. In other instances, control structures, gate level circuits, and full software instruction sequences have not been shown in detail so as not to obscure the embodiments of the invention.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

What is claimed is:

1. A method, including:
forming, on a wafer, integrated circuit elements including a main circuit and a non volatile memory structure associated with the main circuit;
testing a function of the main circuit;
storing a test result associated with the testing in the non volatile memory structure; and
separating from a remainder of the wafer a chip that includes the integrated circuit elements.

2. The method of claim 1, wherein content of the non volatile memory structure cannot be read by the main circuit.

3. The method of claim 1, wherein the non volatile memory structure includes a fuse.

4. The method of claim 3, wherein the fuse is one of a one-time programmable fuse and a many-times programmable fuse.

5. The method of claim 1, wherein content of the non volatile memory structure can be read by the main circuit.

6. The method of claim 1, wherein the main circuit is a radio frequency identification (RFID) circuit.

7. The method of claim 6, wherein the non volatile memory structure is to store a product code associated with the RFID circuit.

8. The method of claim 1, wherein the storing is performed before the separating.

9. The method of claim 1, wherein the storing is performed after the separating.

10. The method of claim 1, further including:
physically probing the wafer to accomplish at least one of the testing and the storing.

11. The method of claim 1, further including:
directing radio frequency energy at the wafer to accomplish at least one of the testing and the storing.

12. The method of claim 1, wherein the main circuit is associated with an on-chip antenna after the separating, and wherein storing the test result includes transmitting a signal that is received by the on-chip antenna.

13. The method of claim 12, wherein the main circuit is a radio frequency identification (RFID) circuit, and the test result is a product code associated with the RFID circuit.

14. The method of claim 1, wherein the test result includes one of a passed result, a failed result, and a grade.

15. The method of claim 1, wherein the storing is performed only if the function has passed the test.

16. The method of claim 1, wherein the storing is performed only if the function has failed the test.

17. The method of claim 1, wherein the storing further includes:
storing at least a part of the test result as a plurality of individual results corresponding to a plurality of individual tests.

18. The method of claim 1, wherein the storing further includes:
storing at least a part of the test result as at least one aggregate result of multiple tests.

19. A wafer having formed thereon integrated circuit elements comprising:
a first main circuit; and
a first non volatile memory structure associated with the first main circuit, the first non volatile memory structure having stored therein a test result associated with prior testing of a function of the first main circuit.

20. The wafer of claim 19, wherein content of the first non volatile memory structure cannot be read by the first main circuit.

21. The wafer of claim 19, wherein the first non volatile memory structure includes a fuse.

22. The wafer of claim 21, wherein the fuse is one of a one-time programmable fuse and a many-times programmable fuse.

23. The wafer of claim 19, wherein content of the first non volatile memory structure can be read by the first main circuit.

24. The wafer of claim 19, wherein the first main circuit is a radio frequency identification (RFID) circuit.

25. The wafer of claim 24, wherein the first memory structure is to store a product code associated with the RFID circuit.

26. The wafer of claim 19, wherein the integrated circuit elements further include:
a second main circuit that is a substantial duplicate of the first main circuit; and
a second non volatile memory structure associated with the second main circuit, the second memory structure having stored therein a test result associated with prior testing of a function of the second main circuit.

27. The wafer of claim 26, wherein the first and the second main circuits are radio frequency identification (RFID) circuits.

28. The wafer of claim 26, wherein the integrated circuit elements further include:
a first on-chip antenna associated with the first main circuit, and
a second on-chip antenna associated with the second main circuit.

29. The wafer of claim 19, wherein the test result comprises one of a passed result, a failed result, and a grade.

30. The wafer of claim 19, wherein the test result comprises a passed result, and excludes a failed result.

31. The wafer of claim 30, wherein the main circuit is a radio frequency identification (RFID) circuit, and the test result comprises a product code associated with the RFID circuit.

32. The wafer of claim 19, wherein the test result comprises a failed result, and excludes a passed result.

33. The wafer of claim 19, wherein the test result comprises individual results of multiple tests.

34. The wafer of claim 19, wherein the test result comprises at least one aggregate result of multiple tests.

35. A device, including:
a chip having formed thereon integrated circuit elements including a main circuit and an associated non volatile memory structure having stored therein a test result associated with prior testing of a function of the main circuit.

36. The device of claim 35, wherein content of the non volatile memory structure cannot be read by the main circuit.

37. The device of claim 35, wherein the non volatile memory structure includes a fuse.

38. The device of claim 37, wherein the fuse is one of a one-time programmable fuse and a many-times programmable fuse.

39. The device of claim 35, wherein content of the non volatile memory structure can be read by the main circuit.

40. The device of claim 35, wherein the main circuit is a radio frequency identification (RFID) circuit.

41. The device of claim 40, wherein the non volatile memory structure is to store a product code associated with the RFID circuit.

42. The device of claim 35, wherein the integrated circuit elements further include:
an on-chip antenna associated with the main circuit, the on-chip antenna to receive the test result in a signal prior to the test result being stored in the non volatile memory structure.

43. The device of claim 35, further including:
an antenna to couple to the chip.

44. The device of claim 35, further including:
a base for attaching the chip thereon.

45. The device of claim 44, wherein the base comprises one of a carrier, a strap, and an inlay.

46. The device of claim 35, wherein the test result comprises one of a passed result, a failed result, and a grade.

47. The device of claim 35, wherein the test result comprises a passed result, and excludes a failed result.

48. The device of claim 47, wherein the main circuit is a radio frequency identification (RFID) circuit, and the test result is a product code associated with the RFID circuit.

49. The device of claim 35, wherein the test result comprises a failed result, and excludes a passed result.

50. The device of claim 35, wherein the test result comprises individual results of multiple tests.

51. The device of claim 35, wherein the test result comprises at least one aggregate result of multiple tests.

52. A method, including:
preparing a chip having formed thereon integrated circuit elements including a main circuit and a non volatile memory structure for interrogation;
interrogating the chip;
reading, as a result of the interrogation, from the non volatile memory structure a stored test result associated with prior testing of a function of the main circuit; and
processing the chip according to the obtained test result.

53. The method of claim 52, wherein the main circuit is a radio frequency identification (RFID) circuit.

54. The method of claim 53, wherein the test result is a product code associated with the RFID circuit.

55. The method of claim 52, wherein the preparing includes separating the chip from a remainder of a wafer.

56. The method of claim 52, wherein the processing includes:
discarding the chip if reading the stored test result fails.

57. The method of claim 52, wherein the processing includes:
discarding the chip if the stored test result comprises a failed result.

58. The method of claim 52, wherein the processing includes:
retaining the chip only if the stored test result comprises a passed result.

59. The method of claim 52, wherein the processing includes:
segregating, from a plurality of chips, those chips, including the chip, whose stored test result comprises a passed result.

60. The method of claim 52, wherein the processing includes:
segregating, from a plurality of chips, those chips, including the chip, whose stored test result comprises a failed result.

61. The method of claim 52, wherein the processing includes:
rendering the stored test result unreadable.

62. The method of claim 52, wherein the stored test result includes a grade, and wherein the processing includes:
retaining the chip together with other chips that are associated with the same grade.

63. The method of claim 52, wherein the interrogating includes:
probing the chip.

64. The method of claim 52, wherein the interrogating includes:
coupling interrogation circuitry to the chip; and
sending, from the interrogation circuitry to the chip, a request to retrieve the stored test result.

65. The method of claim 52, wherein the interrogating includes:
directing radio frequency energy at the chip; and
receiving backscattered energy from the chip that encodes the stored test result.

66. The method of claim 65, further including:
attaching to the chip an antenna to receive the radio frequency energy.

67. The method of claim 65, wherein the integrated circuit elements include an on-chip antenna associated with the main circuit, and wherein the radio frequency energy is backscattered from the on-chip antenna.

68. The method of claim 52, further including:
prior to the reading, placing the chip on a base.

69. The method of claim 68, wherein the base comprises one of a carrier, a strap, and an inlay.

70. The method of claim 52, wherein the processing includes:
attaching an antenna to the chip.

71. The method of claim 52, wherein the processing includes:
creating a radio frequency identification (RFID) tag using the chip.

72. The method of claim 52, further including:
prior to the reading, assembling the chip into a radio frequency identification (RFID) tag.

73. The method of claim 52, further including:
assembling the chip into a radio frequency identification (RFID) tag using a mass fluidic orientation and assembly technique.

74. The method of claim 52, wherein the reading further includes:
reading the stored test result as a plurality of individual results corresponding to a plurality of individual tests.

75. The method of claim 52, wherein the reading further includes:
reading the stored test result as at least one aggregate result of multiple tests.
